(19) United States
(12) Patent Application Publication
(10) Pub. No.: US 2024/0283218 A1
(43) Pub. Date: Aug. 22, 2024

(54) MATRIX ADDRESSABLE VERTICAL-CAVITY SURFACE-EMITTING LASER ARRAY

(71) Applicant: Lumentum Operations LLC, San Jose, CA (US)

(72) Inventors: Yeyu ZHU, San Jose, CA (US); Eric R. HEGBLOM, Sunnyvale, CA (US); Slava KHASSINE, San Jose, CA (US)

(21) Appl. No.: 18/315,400

(22) Filed: May 10, 2023

Related U.S. Application Data
(60) Provisional application No. 63/485,752, filed on Feb. 17, 2023.

(51) Int. Cl. H01S 5/042; H01S 5/02; H01S 5/0236; H01S 5/0237; H01S 5/42

(52) U.S. Cl. CPC H01S 5/04256; H01S 5/0217; H01S 5/0236; H01S 5/0237; H01S 5/423

(57) ABSTRACT

A vertical-cavity surface-emitting laser (VCSEL) array may include a substrate, a wafer bonding layer over the substrate, and a first metal layer on or within the wafer bonding layer. The first metal layer may include a plurality of first electrodes. The VCSEL array may include an epitaxial region over the first metal layer and the wafer bonding layer. The epitaxial region may be bonded to the wafer bonding layer. The VCSEL array may include a second metal layer over the epitaxial region. The second metal layer may include a plurality of second electrodes. The plurality of first electrodes and the plurality of second electrodes may form a plurality of matrix addressable subarrays of the VCSEL array, where each matrix addressable subarray of the plurality of matrix addressable subarrays includes one or more emitters.

### CROSS-REFERENCE TO RELATED APPLICATION

This patent application claims priority to U.S. Provisional Patent Application No. 63/485,752, filed on Feb. 17, 2023, and entitled “MATRIX ADDRESSABLE VERTICAL-CAVITY SURFACE-EMITTING LASER ARRAY.” The disclosure of the prior application is considered part of and is incorporated by reference into this patent application.

### TECHNICAL FIELD

The present disclosure relates generally to a vertical-cavity surface-emitting laser (VCSEL) array, and to a matrix addressable VCSEL array.

### BACKGROUND

A vertical-emitting device, such as a bottom-emitting or top-emitting VCSEL, is a laser in which a laser beam is emitted in a direction perpendicular to a surface of a substrate (e.g., vertically from a surface of a semiconductor wafer). A typical VCSEL includes an epitaxial region (also referred to as an epi region) grown on the substrate. The epitaxial region may include, for example, a pair of reflectors (e.g., a pair of distributed Bragg reflectors (DBRs)), one or more active regions, or one or more oxidation layers, among other examples. Other layers may be formed on or above the epitaxial region, such as one or more dielectric layers or one or more metal layers. A VCSEL array may provide multiple emitting sources on a single chip for emitting a single beam or multiple discrete beams.

### SUMMARY

In some implementations, a VCSEL array includes a substrate; a wafer bonding layer over the substrate; a first metal layer on or within the wafer bonding layer, the first metal layer including a plurality of first electrodes; an epitaxial region over the first metal layer and the wafer bonding layer, the epitaxial region being bonded to the wafer bonding layer; and a second metal layer over the epitaxial region, the second metal layer including a plurality of second electrodes, wherein the plurality of first electrodes and the plurality of second electrodes form a plurality of matrix addressable subarrays of the VCSEL array, each matrix addressable subarray of the plurality of matrix addressable subarrays including one or more emitters.

In some implementations, a method includes forming an epitaxial region on a first substrate; forming a first metal layer on a first side of the epitaxial region, the first metal layer including a plurality of first electrodes; bonding, using a wafer bonding material, the first metal layer and the first side of the epitaxial region to a second substrate such that the first metal layer is between the first side of the epitaxial region and the second substrate; removing the first substrate to expose a portion of a second side of the epitaxial region; and forming a second metal layer on the second side of the epitaxial region, the second metal layer including a plurality of second electrodes, wherein the plurality of first electrodes and the plurality of second electrodes form a plurality of matrix addressable subarrays of an emitter array, each matrix addressable subarray of the plurality of matrix addressable subarrays including one or more emitters.

In some implementations, a VCSEL array includes a substrate comprising a recess on a first side of the substrate; a first metal layer within the recess on the first side of the substrate, the first metal layer including a plurality of first electrodes; an epitaxial region on a second side of the substrate; and a second metal layer over the epitaxial region, the second metal layer including a plurality of second electrodes, wherein the plurality of first electrodes and the plurality of second electrodes form a plurality of matrix addressable subarrays of the VCSEL array, each matrix addressable subarray of the plurality of matrix addressable subarrays including one or more emitters.

In some implementations, a method includes forming an epitaxial region on a substrate; forming a second metal layer on a second side of the epitaxial region, the second metal layer including a plurality of second electrodes; forming a recess in the substrate; and forming a first metal layer over the substrate on a first side of the epitaxial region, the first metal layer includes a plurality of first electrodes, wherein at least a portion of the first metal layer is formed within the recess, and wherein the plurality of first electrodes and the plurality of second electrodes form a plurality of matrix addressable subarrays of an emitter array, each matrix addressable subarray of the plurality of matrix addressable subarrays including one or more emitters.

### BRIEF DESCRIPTION OF THE DRAWINGS

FIG. 1 is an example illustrating an example simplified layout of 2D matrix addressable VCSEL array.

FIGS. 2A and 2B are diagrams illustrating an example of a 2D matrix addressable VCSEL array realized using a wafer bonding technique as described herein.

FIGS. 3A-3E are diagrams illustrating an example process for realizing a 2D matrix addressable VCSEL array using a wafer bonding technique as described herein.

FIGS. 4A and 4B are diagrams illustrating an example of a 2D matrix addressable VCSEL array realized using a deep etching technique as described herein.

FIGS. 5A-5D are diagrams illustrating an example process for realizing a 2D matrix addressable VCSEL array using a deep etching technique as described herein.

### DETAILED DESCRIPTION

The following detailed description of example implementations refers to the accompanying drawings. The same reference numbers in different drawings may identify the same or similar elements.

A group of VCSELs may be arranged on a chip to form a VCSEL array. A VCSEL array may take the form of, for example, a rectangular grid emitter array (e.g., where multiple VCSELs are uniformly spaced and a given isolation region may be shared by two or more VCSELs) or a non-grid emitter array (e.g., where VCSELs are not uniformly spaced and a given VCSEL may require isolation regions which may or may not be shared).

Some VCSEL arrays may have VCSELs arranged in a matrix addressable layout. For example, a two-dimensional (2D) matrix addressable VCSEL array may include a set of anode traces forming a set of columns and a set of cathode traces forming a set of rows, with sets of VCSELs disposed at intersections between these anode traces and cathode traces. The anode traces may be referred to as “anodes” or “an anode” and the cathode traces may be referred to as “cathodes” or “a cathode”. By selectively controlling current to different cathode traces and anode traces (e.g., using sets of switches), a controller may send current to selected sets of VCSELs to cause the selected sets of VCSELs to output one or more beams. A matrix addressable VCSEL array may work with single-photon avalanche photodiode (SPAD) arrays with block readout in order to enable, for example, a true solid-state light detection and ranging (LiDAR) sensor that does not require mechanically moving parts for scanning laser beams.

In a typical VCSEL array, an anode is on a top surface (e.g., on an epitaxial side of a substrate) and a common cathode is on a bottom surface (e.g., on a non-epitaxial side of the substrate). However, for a 2D matrix addressable VCSEL array, in order to individually control each subarray, the anodes and cathodes may in some cases both be on the top surface for a top-emitting design.

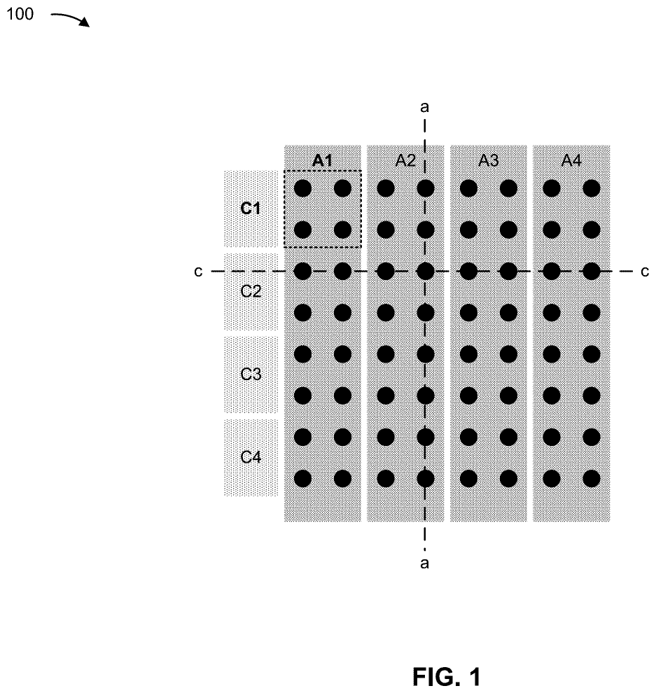

FIG. 1 is an example illustrating an example simplified layout of 2D matrix addressable VCSEL array. The example shown in FIG. 1 comprises four anodes (A1 through A4) and four cathodes (C1 through C4). In this example, the anodes and cathodes are arranged so as to create 16 subarrays of four VCSELs each. Here, a given cathode contacts VCSELs across a row and a given anode contacts VCSELs along a column. In operation, by applying a positive voltage to the desired anode (column) and a negative voltage to a desired cathode (row), VCSELs in a subarray at an intersection of the selected anode and cathodes will be powered on. For example, by applying a positive voltage to anode A1 and a negative voltage to cathode C1, VCSELs in a subarray at an intersection of the anode A1 and the cathode C1 (indicated in FIG. 1 by a dashed square) will be powered on. In some applications, such as a LiDAR application, VCSELs with multiple junctions are needed (e.g., to provide higher peak power and efficiency), and so a bias voltage applied may be relatively high (e.g., above 35 Volts (V)).

In some cases, to enable both the anode and the cathode to be formed on the top surface, a sandwiched insolation layer (e.g., a dielectric film, a benzocyclcobutane (BCB) layer, a polybenzoxazole (PBO) layer, or the like) needs to be added in order to isolate the overlapped plated metal layers that form the anodes and the cathodes. However, the plated metal anodes and cathodes have a relatively rough surface, which in combination with the use of a relatively high bias voltage, reduces reliability of the VCSEL array. To address this issue, the anode could be formed on the top surface and the cathode could be formed on the bottom surface to eliminate the overlap of the metal layers. However, a thickness of the substrate (even after wafer thinning) may be significant (e.g., approximately 100 micrometers (μm)), which can make the cathode traces very difficult to isolate by implant isolation, etching or contact with deep vias or the like. To realize a 2D matrix addressable VCSEL array with separated plated metal layers (e.g., an anode on an epitaxial side and a cathode on the non-epitaxial side), a distance between a plated metal layer at or near the bottom surface and the bottom mirror DBR pairs of the epitaxial region should be reduced.

Some implementations described herein enable an improved matrix addressable VCSEL array in which a first metal layer is separate from a second metal layer, and in which a distance between the first metal layer and bottom mirrors of the VCSEL array is reduced, thereby reducing current leakage and improving reliability.

In some implementations, the improved matrix addressable VCSEL array is realized using a wafer bonding technique. For example, in some implementations, a VCSEL array may include a wafer bonding layer over a substrate, and a first metal layer on or within the wafer bonding layer, with the first metal layer including a plurality of first electrodes (e.g., a cathodes). The VCSEL array may further include an epitaxial region over the first metal layer and the wafer bonding layer, with the epitaxial region being bonded to the wafer bonding layer. The VCSEL array may further include a second metal layer over the epitaxial region, with the second metal layer including a plurality of second electrodes (e.g., anodes). Here, the plurality of first electrodes and the plurality of second electrodes form a plurality of matrix addressable subarrays of the VCSEL array.

In some implementations, the improved matrix addressable VCSEL array is realized using a deep etching technique. For example, in some implementations, a VCSEL array may include a substrate comprising a recess (e.g., an etched region) on a first side of the substrate. The VCSEL array may further include a first metal layer within the recess, with the first metal layer including a plurality of first electrodes (e.g., cathodes). The VCSEL array may further include an epitaxial region on a second side of the substrate, and a second metal layer over the epitaxial region, with the second metal layer including a plurality of second electrodes (e.g., anodes). Here, the plurality of first electrodes and the plurality of second electrodes form a plurality of matrix addressable subarrays of the VCSEL array.

The improved matrix addressable VCSEL arrays described herein (e.g., a VCSEL array realized using the wafer bonding technique or a VCSEL array realized using the deep etching technique) eliminates overlap of metal layers of the VCSEL array by providing the first metal layer on an opposite side of the epitaxial region of the VCSEL array (e.g., such that anodes are formed on the top surface and cathodes could be formed on the bottom surface), thereby improving reliability of the VCSEL array (e.g., when a relatively high bias voltage is applied). Further, a distance between a plated metal on a bottom side of the VCSEL array and a bottom mirror of the VCSEL is reduced, which makes it possible to isolate adjacent metal traces with ion implantation or with shallower, narrower trenches or without deep widely spaced vias. Additional details are provided below.

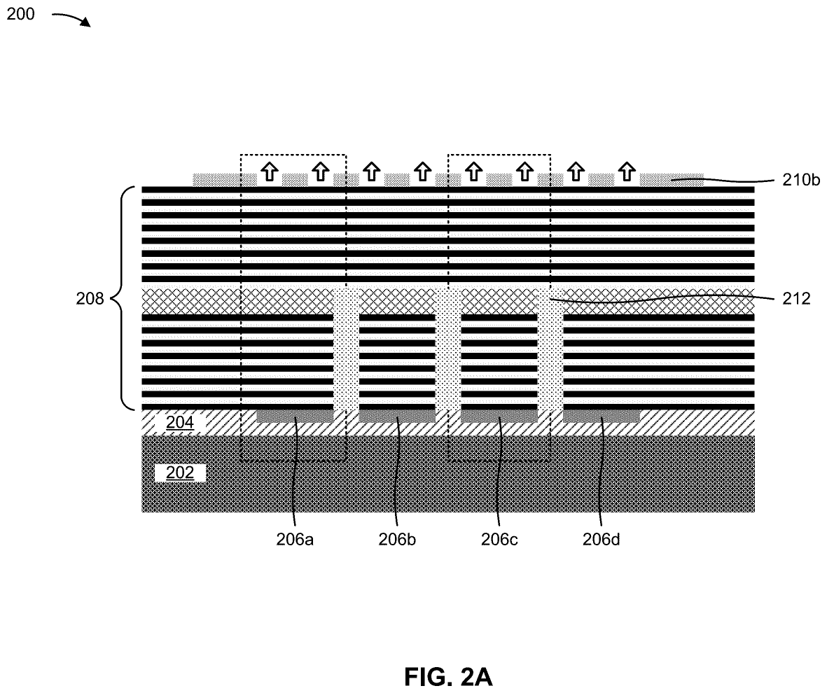

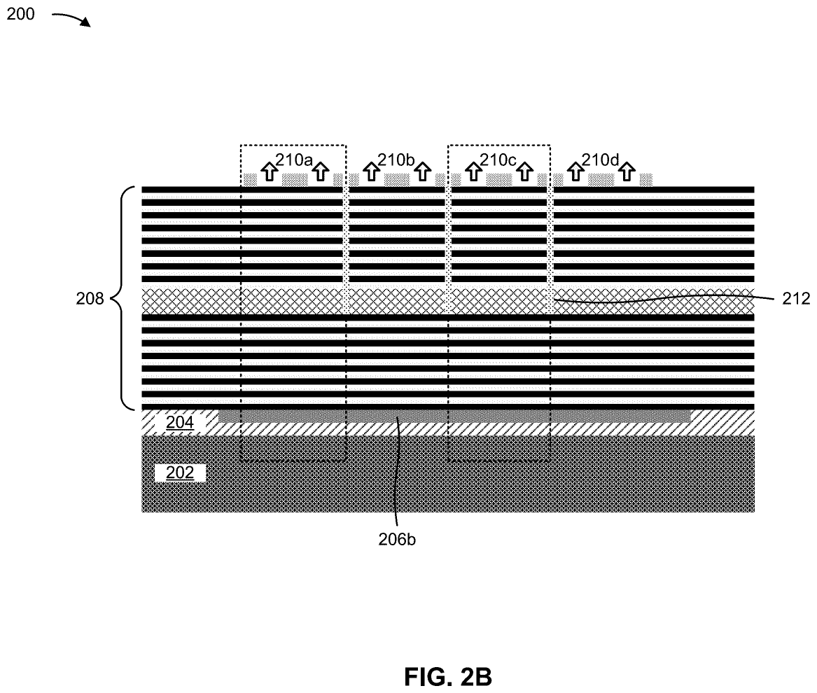

FIGS. 2A and 2B are diagrams illustrating an example of a 2D matrix addressable VCSEL array 200 realized using a wafer bonding technique as described herein. As shown in FIGS. 2A and 2B, the 2D matrix addressable VCSEL array 200 (herein referred to as VCSEL array 200) may include a substrate 202, a wafer bonding layer 204, a first metal layer 206, an epitaxial region 208, a second metal layer 210, and one or more isolation regions 212. FIG. 2A illustrates an example cross-section along a trace of the second metal layer 210 (e.g., along an anode trace, an example of which is indicated by line a-a in FIG. 1). FIG. 2B illustrates an example cross-section along a trace of the first metal layer 206 (e.g., along a cathode trace, an example of which is indicated by line c-c in FIG. 1).

The substrate 202 includes a supporting material upon which or within which one or more layers or features of the VCSEL array 200 are grown, fabricated, or bonded, as described herein. In some implementations, the substrate 202 may be formed from a semiconductor material, such as silicon (Si), gallium arsenide (GaAs), silicon carbide (SiC), indium phosphide (InP), or another type of semiconductor material. In some implementations, the substrate 202 comprises a semi-insulating type of material. In some implementations, the semi-insulating type of material may be used when, for example, the VCSEL array 200 includes one or more bottom-emitting emitters in order to reduce optical absorption from the substrate 202. Alternatively, the substrate 202 may in some implementations comprise a conducting material. In such an implementation, the VCSEL may include an isolation layer (not shown) between the substrate 202 and the wafer bonding layer 204. In some implementations, the isolation layer between the substrate 202 and the wafer bonding layer 204 serves to at least partially electrically isolate the epitaxial region 208 from the substrate 202.

The wafer bonding layer 204 comprises a wafer bonding material that bonds the epitaxial region 208 and the substrate 202. For example, the wafer bonding layer 204 may be a bonding material that is deposited or formed on the first metal layer 206 and exposed portions of the epitaxial region 208 (e.g., such that the wafer bonding layer 204 is bonded to the epitaxial region 208). The wafer bonding layer 204 may then be bonded to the substrate 202 by the wafer bonding layer 204 (e.g., such that the first metal layer 206 and the epitaxial region 208 are bonded to the substrate 202 by the wafer bonding layer 204). In some implementations, the wafer bonding layer 204 comprises an adhesive bonding material. For example, the wafer bonding layer 204 may comprise BCB, silicon dioxide (SiO₂), or an epoxy material such as SU-8. Additionally, or alternatively, the wafer bonding layer 204 may comprise a solder bonding material. Additionally, or alternatively, the wafer bonding layer 204 may comprise a thermocompression bonding material. For example, the thermocompression bonding material may comprise two metal layers (e.g., two gold (Au) layers), and the two metal layers can be brought into atomic contact by simultaneous application of force and heat to achieve bonding.

The first metal layer 206 includes a metal layer that forms a plurality of first electrodes for the VCSEL array 200. For example, the first metal layer 206 may in some implementations form a plurality of cathodes for the VCSEL array 200, where each cathode contacts VCSELs across a respective row of the VCSEL array 200. As another example, the first metal layer 206 may in some implementations form a plurality of anodes for the VCSEL array 200, where each anode contacts VCSELs across a respective row of the VCSEL array 200. The example shown in FIG. 2A illustrates the first metal layer 206 as forming four electrodes (e.g., as indicated by references 206a through 206d). In some implementations, the first metal layer 206 is formed on the epitaxial region 208 prior to the epitaxial region 208 being bonded to the wafer bonding layer 204. In some implementations, the first metal layer 206 may include an annealed metallization layer, such as a gold-germanium-nickel (AuGeNi) layer or a palladium-germanium-gold (PdGeAu) layer, among other examples.

The epitaxial region 208 is a region of the VCSEL array 200 designed to generate laser light. For example, the epitaxial region 208 may include a bottom mirror structure that serves as a bottom reflector of an optical resonator of the VCSEL array 200 (e.g., a DBR, a dielectric mirror, or another type of mirror structure), one or more active regions that include layers where electrons and holes recombine to emit light and a top mirror structure that serves as a top reflector of the optical resonator of the VCSEL array 200 (e.g., a DBR, a dielectric mirror, or another type of mirror structure). In some implementations, the emission wavelength of the VCSEL array 200 may be in a range from approximately 200 nanometers (nm) to 3000 nm depending upon the materials used for the one or more active regions and the mirror structures (although a given VCSEL array 200 may emit within approximately a 10 nm range at use temperatures). Notably, the epitaxial region 208 is shown for as an abstract example for illustrative purposes and may include one or more other layers. For example, the epitaxial region 208 may include one or more oxidation layers (e.g., one or more layers that form apertures that provide optical and electrical confinement for the VCSELs of the VCSEL array 200), among other examples. Notably, in the VCSEL array 200, the epitaxial region 208 is not grown or deposited on the substrate 202. Rather, the epitaxial region 208 is grown separately (e.g., on a removable substrate 302, which may be for example a GaAs substrate) and bonded to the substrate 202 by the wafer bonding layer 204.

The second metal layer 210 includes a metal layer that forms a plurality of second electrodes for the VCSEL array 200. For example, the second metal layer 210 may in some implementations form a plurality of anodes for the VCSEL array 200, where each anode contacts VCSELs across a respective column of the VCSEL array 200. As another example, the second metal layer 210 may in some implementations form a plurality of cathodes for the VCSEL array 200, where each cathode contacts VCSELs across a respective column of the VCSEL array 200. The example shown in FIG. 2B illustrates the second metal layer 210 as forming four electrodes (e.g., as indicated by references 210a through 210d). In some implementations, the second metal layer 210 may include an annealed metallization layer, such as a AuGeNi layer or a PdGeAu layer, among other examples.

In some implementations, the plurality of first electrodes formed by the first metal layer 206 and the plurality of second electrodes formed by the second metal layer 210 form a plurality of matrix addressable subarrays of the VCSEL array 200, where each matrix addressable subarray of the plurality of matrix addressable subarrays includes one or more emitters of the VCSEL array 200. For example, the first metal layer 206 and the second metal layer 210 may be formed so as to create a plurality of subarrays, where each subarray includes at least one VCSEL. Here, a given electrode formed by the first metal layer 206 may contact VCSELs across a row and a given electrode formed by the second metal layer 210 may contact VCSELs along a column. In operation, VCSELs in a subarray at an intersection of a selected first metal layer 206 electrode and a second metal layer 210 electrode can be powered on by appropriate application of voltages (e.g., as described with respect to FIG. 1).

In some implementations, the VCSEL array 200 includes one or more isolation regions 212. An isolation region 212 is a region associated with isolating a given electrode from one or more other electrodes. For example, as illustrated in FIG. 2A, the VCSEL array 200 may include isolation regions 212 that that at least partially isolate electrodes of the plurality of first electrodes (e.g., cathodes) formed by the first metal layer 206 from one another. As another example, as illustrated in FIG. 2B, the VCSEL array 200 may include isolation regions 212 that that at least partially isolate electrodes of the plurality of second electrodes (e.g., anodes) formed by the second metal layer 210 from one another. In some implementations, a given isolation region 212 may be an ion implantation region (e.g., an isolation region formed through ion implantation of a portion of the epitaxial region 208). Additionally, or alternatively, a given isolation region may be an etched region (e.g., an isolation region formed through etching of a portion of the epitaxial region 208).

In this way, the VCSEL array 200 eliminates overlap of metal layers by providing the first metal layer 206 on an opposite side of the epitaxial region 208, thereby improving reliability of the VCSEL array 200 (e.g., when a relatively high bias voltage is applied). Further, a distance between a plated metal (e.g., the first metal layer 206) nearer to a bottom side of the VCSEL array 200 and a bottom mirror of the VCSEL array 200 within the epitaxial region 208 is reduced due to the first metal layer 206 being between the substrate 202 and the epitaxial region 208 (rather than on a bottom side of the substrate 202), which reduces or eliminates current leakage between adjacent traces of the first metal layer 206, thereby improving performance and reliability of the VCSEL array 200.

As indicated above, FIGS. 2A and 2B are provided as an example. Other examples may differ from what is described with regard to FIGS. 2A and 2B. Further, the number and arrangement of layers shown in FIGS. 2A and 2B are provided as an example. For example, while the VCSEL array 200 shown in FIGS. 2A and 2B is illustrated as top-emitting VCSEL array, the VCSEL array 200 may in some implementations be bottom-emitting VCSEL array. In practice, there may be additional layers, fewer layers, different layers, or differently arranged layers than those shown in FIGS. 2A and 2B.

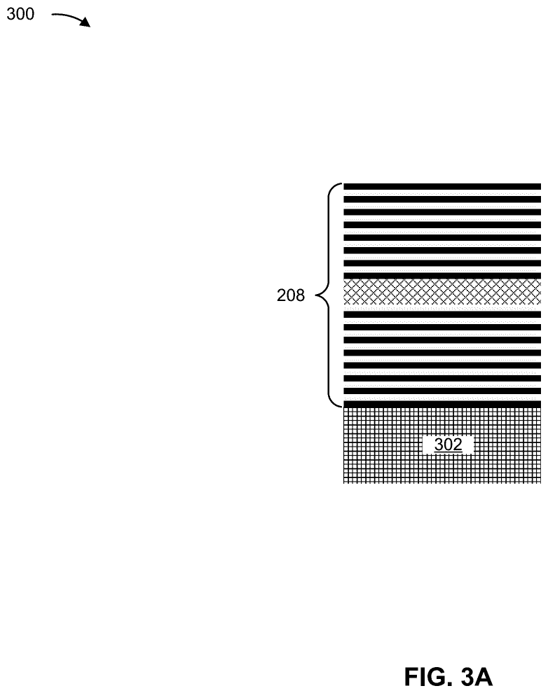

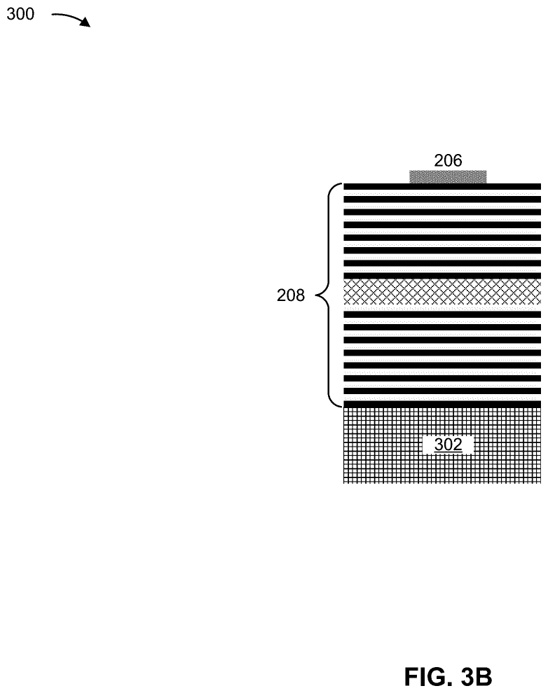

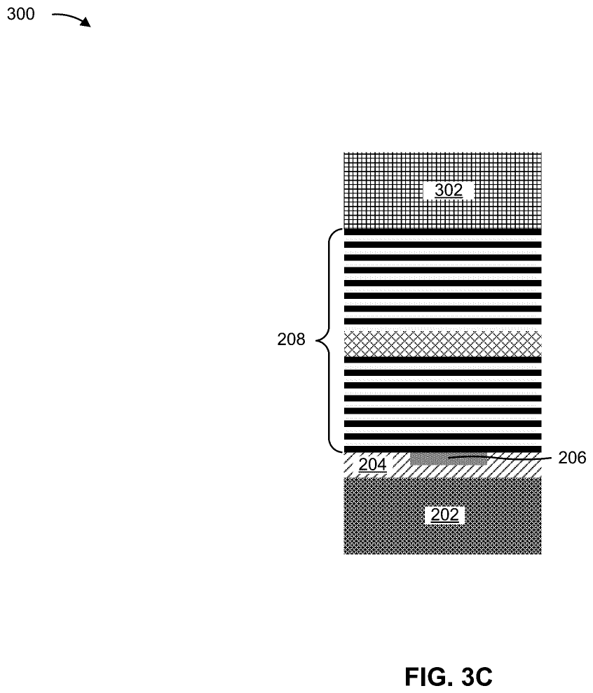

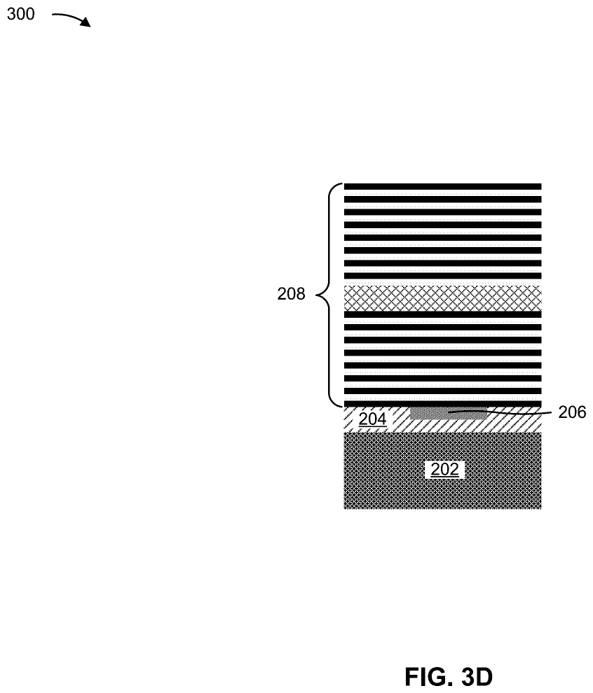

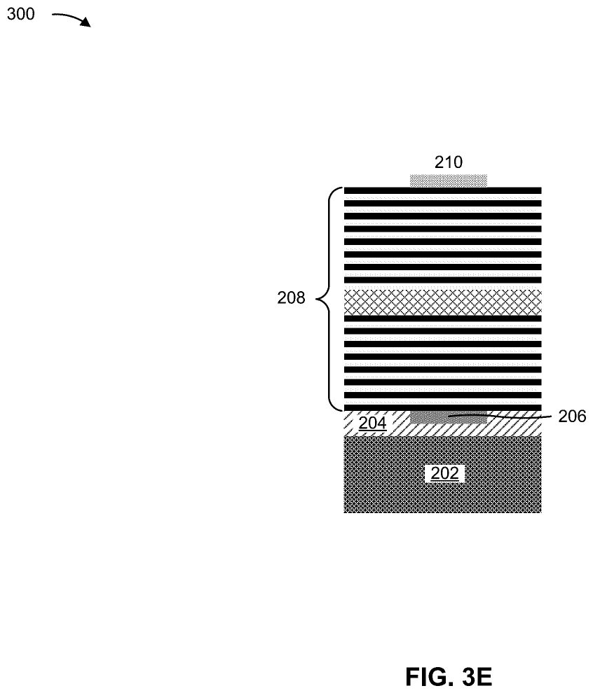

FIGS. 3A-3E are diagrams illustrating an example process 300 for realizing the VCSEL array 200 using a wafer bonding technique as described herein.

As shown in FIG. 3A, process 300 may include forming an epitaxial region on a first substrate. For example, an epitaxial region 208 may be formed on a removable substrate 302. The removable substrate 302 is a substrate on which the epitaxial region 208 may be formed and, after bonding of the epitaxial region 208 and the substrate 202 by the wafer bonding layer 204, may be removed.

As shown in FIG. 3B, process 300 may include forming a first metal layer on a first side of the epitaxial region, the first metal layer including a plurality of first electrodes. For example, a first metal layer 206 may be formed on a first side of the epitaxial region 208, the first metal layer 206 including a plurality of first electrodes (e.g., a plurality of cathode traces).

As shown in FIG. 3C, process 300 may include bonding, using a wafer bonding material, the first metal layer and the first side of the epitaxial region to a second substrate such that the first metal layer is between the first side of the epitaxial region and the second substrate. For example, using the wafer bonding layer 204, the first metal layer 206 and the first side of the epitaxial region 208 may be bonded to the substrate 202 such that the first metal layer 206 is between the first side of the epitaxial region 208 and the substrate 202.

As shown in FIG. 3D, process 300 may include removing the first substrate to expose a portion of a second side of the epitaxial region. For example, the removable substrate 302 may be removed to expose a portion of a second side of the epitaxial region 208.

As shown in FIG. 3E, process 300 may include forming a second metal layer on the second side of the epitaxial region, the second metal layer including a plurality of second electrodes, wherein the plurality of first electrodes and the plurality of second electrodes form a plurality of matrix addressable subarrays of an emitter array, each matrix addressable subarray of the plurality of matrix addressable subarrays including one or more emitters. For example, a second metal layer 210 may be formed on the second side of the epitaxial region 208, the second metal layer 210 including a plurality of second electrodes (e.g., a plurality of anode traces), wherein the plurality of first electrodes and the plurality of second electrodes form a plurality of matrix addressable subarrays of an VCSEL array 200, each matrix addressable subarray of the plurality of matrix addressable subarrays including one or more emitters.

Process 300 may include additional implementations, such as any single implementation or any combination of implementations described below and/or in connection with one or more other processes described elsewhere herein.

In a first implementation, the wafer bonding material (e.g., the wafer bonding layer 204) comprises at least one of an adhesive bonding material, a solder bonding material, or a thermocompression bonding material.

In a second implementation, alone or in combination with the first implementation, process 300 includes forming an isolation region (e.g., isolation region 212) associated with isolating a first electrode of the plurality of first electrodes from a second electrodes of the plurality of first electrodes. In some implementations, the isolation region 212 is an ion implantation region. In some implementations, the isolation region 212 is an etched region.

In a third implementation, alone or in combination with any one or more of the first and second implementations, the plurality of first electrodes is a plurality of cathodes and the plurality of second electrodes is a plurality of anodes.

In a fourth implementation, alone or in combination with any one or more of the first and second implementations, the plurality of first electrodes is a plurality of anodes and the plurality of second electrodes is a plurality of cathodes.

In a fifth implementation, alone or in combination with any one or more of the first through fourth implementations, the VCSEL array 200 is a top-emitting VCSEL array.

In a sixth implementation, alone or in combination with any one or more of the first through fourth implementations, the VCSEL array 200 is a bottom-emitting VCSEL array.

Although FIGS. 3A-3E show example operations of process 300, in some implementations, process 300 includes additional operations, fewer operations, different operations, or differently ordered operations than those depicted in FIGS. 3A-3E. Additionally, or alternatively, two or more of the operations of process 300 may be performed in parallel.

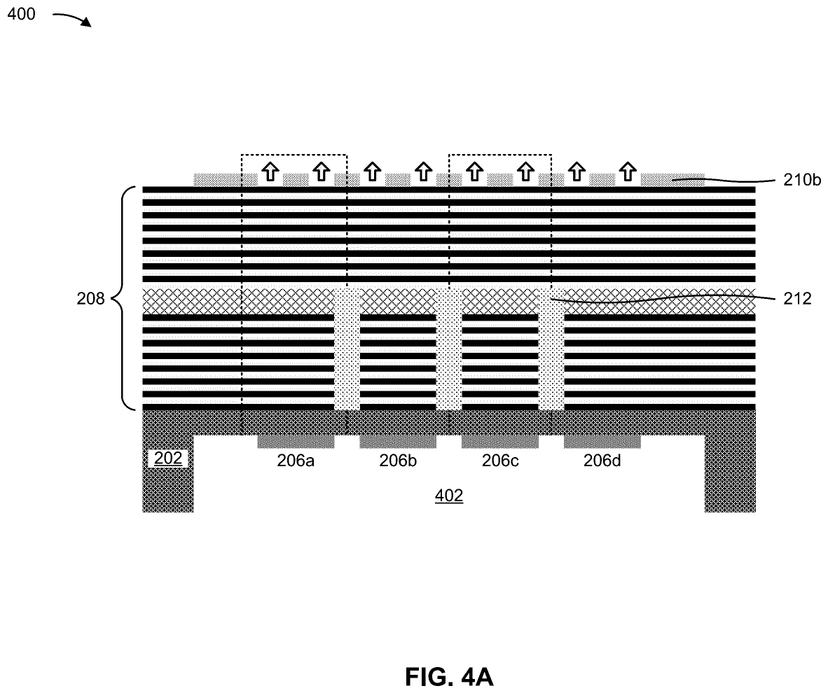

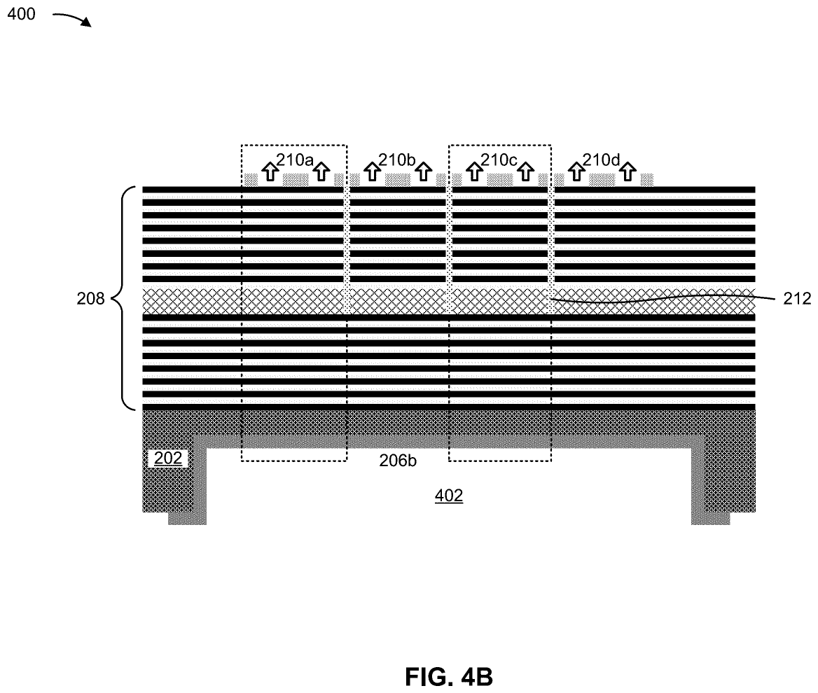

FIGS. 4A and 4B are diagrams illustrating an example of a VCSEL array 400 realized using a deep etching technique as described herein. As shown in FIG. 4A, the 2D matrix addressable VCSEL array 400 (herein referred to as VCSEL array 400) may include a substrate 202 comprising a recess 402, a first metal layer 206, an epitaxial region 208, a second metal layer 210, and one or more isolation regions 212. FIG. 4A illustrates an example cross-section along a trace of the second metal layer 210 (e.g., along an anode trace, an example of which is indicated by line a-a in FIG. 1). FIG. 4B illustrates an example cross-section along a trace of the first metal layer 206 (e.g., along a cathode trace, an example of which is indicated by line c-c in FIG. 1). The substrate 202, the first metal layer 206, the epitaxial region 208, the second metal layer 210, and the one or more isolation regions 212 may have characteristics as described above with respect to FIGS. 2A and 2B.

As shown in FIGS. 4A and 4B, the substrate 202 may in some implementations comprise the recess 402. In some implementations, the recess 402 may be formed using a deep etching technique. In some implementations, the recess 402 may be formed such that the sidewalls of the recess 402 are sloped with respect to (e.g., non-perpendicular to) a surface of the substrate 202. In some implementations, the recess 402 has a depth that is less than approximately 100 μm. In some implementations, a thickness of the substrate 202 within the recess 402 is approximately 20 μm. For example, prior to etching the substrate 202 may have a thickness of approximately 60 μm, and deep etching can utilized to form a recess 402 having a depth of approximately 40 μm (e.g., such that a portion of the substrate 202 within the recess 402 has a thickness of approximately 20 μm).

In some implementations, the first metal layer 206 may be formed such that at least a portion of the first metal layer 206 is within the recess 402 (e.g., such that a portion of each of the plurality of second electrodes is on a surface of the substrate 202 that is closest to the epitaxial region 208). In some implementations, a width of a given electrode in the plurality of first electrodes may be greater than approximately 10 μm (e.g., wide traces may be formed on the substrate 202 within the recess 402). In some implementations, to form the first metal layer 206 in the recess 402, an evaporated metal contact may be formed in the recess 402, after which a plated metal that climbs on the (sloped) sidewalls of the recess 402 may be formed.

In this way, the VCSEL array 400 eliminates overlap of metal layers by providing the first metal layer 206 on an opposite side of the epitaxial region 208, thereby improving reliability of the VCSEL array 400 (e.g., when a relatively high bias voltage is applied). Further, a distance between a plated metal (e.g., the first metal layer 206) nearer to a bottom side of the VCSEL array 400 and a bottom mirror of the VCSEL array 400 within the epitaxial region 208 is reduced due to the first metal layer 206 being formed within the recess 402 of the substrate 202, which reduces or eliminates current leakage between adjacent traces of the first metal layer 206, thereby improving performance and reliability of the VCSEL array 400.

As indicated above, FIGS. 4A and 4B are provided as an example. Other examples may differ from what is described with regard to FIGS. 4A and 4B. Further, the number and arrangement of layers shown in FIGS. 4A and 4B are provided as an example. In practice, there may be additional layers, fewer layers, different layers, or differently arranged layers than those shown in FIGS. 4A and 4B. For example, while the VCSEL array 400 shown in FIGS. 4A and 4B is illustrated as top-emitting VCSEL array, the VCSEL array 400 may in some implementations be bottom-emitting VCSEL array.

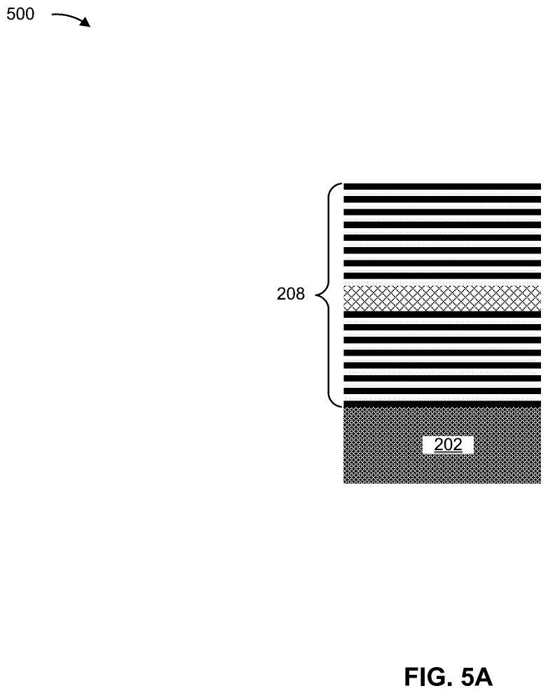

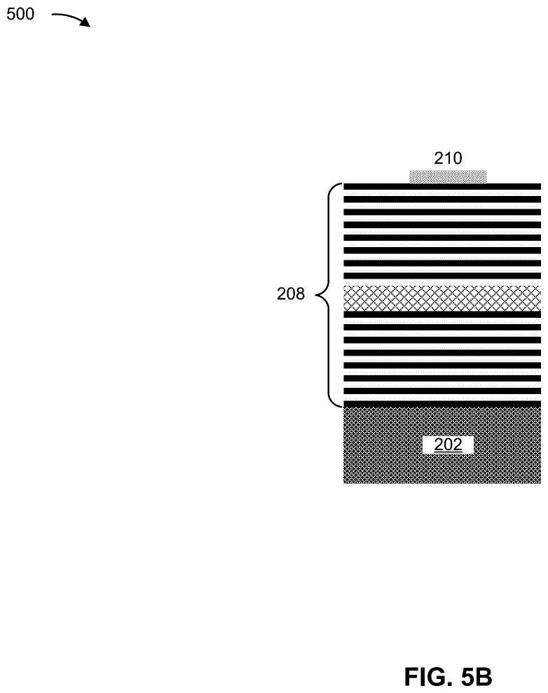

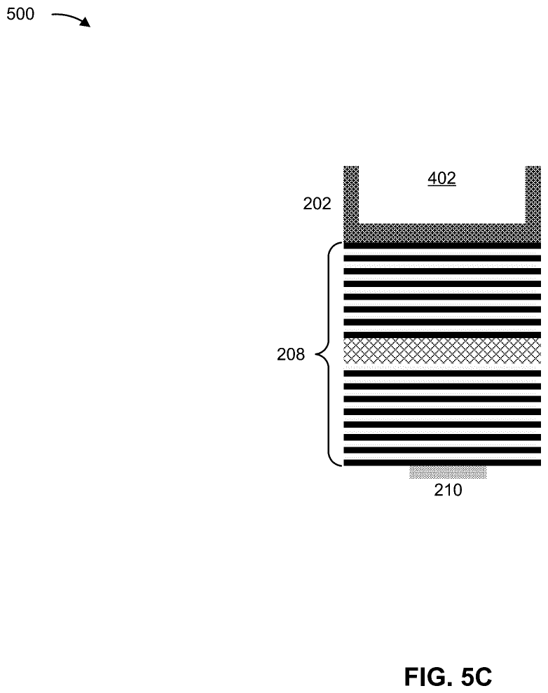

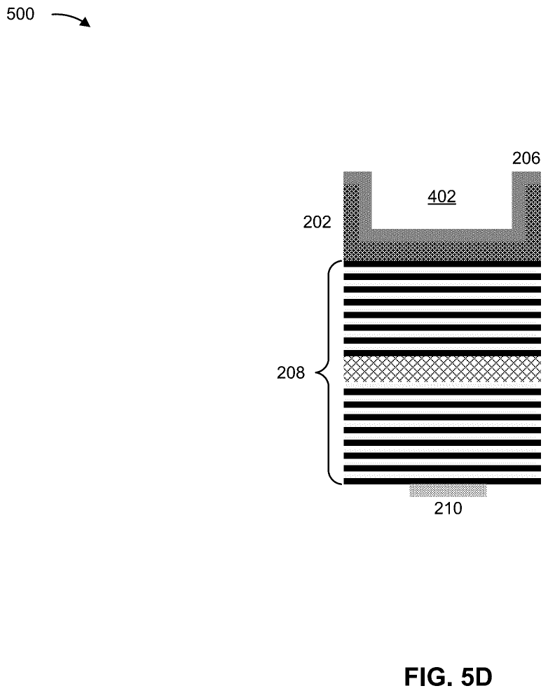

FIGS. 5A-5D are diagrams illustrating an example process 500 for realizing a 2D matrix addressable VCSEL array 400 using a deep etching technique as described herein.

As shown in FIG. 5A, process 500 may include forming an epitaxial region on a substrate. For example, the epitaxial region 208 may be formed on the substrate 202.

As shown in FIG. 5B, process 500 may include forming a second metal layer on a second side of the epitaxial region, the second metal layer including a plurality of second electrodes. For example, the second metal layer 210 may be formed on a second side of the epitaxial region 208, the second metal layer 210 including a plurality of second electrodes.

As shown in FIG. 5C, process 500 may include forming a recess in the substrate. For example, the recess 402 may be formed in the substrate. In some implementations, the recess 402 may be formed such that the sidewalls of the recess 402 are sloped with respect to (e.g., non-perpendicular to) a surface of the substrate 202.

As shown in FIG. 5D, process 500 may include forming a first metal layer over the substrate on a first side of the epitaxial region, the first metal layer includes a plurality of first electrodes, wherein at least a portion of the first metal layer is formed within the recess, and wherein the plurality of first electrodes and the plurality of second electrodes form a plurality of matrix addressable subarrays of an emitter array, each matrix addressable subarray of the plurality of matrix addressable subarrays including one or more emitters. For example, the first metal layer 206 may be formed over the substrate 202 on a first side of the epitaxial region 208, the first metal layer 206 including a plurality of first electrodes, wherein at least a portion of the first metal layer 206 is formed within the recess 402, and wherein the plurality of first electrodes and the plurality of second electrodes form a plurality of matrix addressable subarrays of the VCSEL array 400, each matrix addressable subarray of the plurality of matrix addressable subarrays including one or more emitters. In some implementations, forming the first metal layer 206 in the recess 402 comprises forming an evaporated metal contact on one or more surfaces of the recess 402, and then forming a plated metal that climbs on the metal contact on the (sloped) sidewalls of the recess 402.

Process 500 may include additional implementations, such as any single implementation or any combination of implementations described below and/or in connection with one or more other processes described elsewhere herein.

In a first implementation, a width of an electrode in the plurality of first electrodes is greater than 10 μm.

In a second implementation, alone or in combination with the first implementation, the recess 402 has a depth that is less than approximately 100 μm.

In a third implementation, alone or in combination with any one or more of the first and second implementations, a thickness of the substrate 202 within the recess 402 is approximately 20 μm.

In a fourth implementation, alone or in combination with any one or more of the first through third implementations, process 500 includes forming an isolation region 212 associated with isolating a first electrode of the plurality of first electrodes from a second electrode of the plurality of first electrodes.

In a fifth implementation, alone or in combination with any one or more of the first through fourth implementations, process 500 includes forming an isolation layer between the substrate 202 and the epitaxial region 208.

In a sixth implementation, alone or in combination with any one or more of the first through fifth implementations, the plurality of first electrodes is a plurality of cathodes and the plurality of second electrodes is a plurality of anodes.

In a seventh implementation, alone or in combination with any one or more of the first through fifth implementations, the plurality of first electrodes is a plurality of anodes and the plurality of second electrodes is a plurality of cathodes.

In an eighth implementation, alone or in combination with any one or more of the first through seventh implementations, the VCSEL array 400 is a top-emitting VCSEL array.

In a ninth implementation, alone or in combination with any one or more of the first through seventh implementations, the VCSEL array 400 is a bottom-emitting VCSEL array.

Although FIG. 5 shows example blocks of process 500, in some implementations, process 500 includes additional blocks, fewer blocks, different blocks, or differently arranged blocks than those depicted in FIG. 5. Additionally, or alternatively, two or more of the blocks of process 500 may be performed in parallel.

Although FIGS. 5A-5D show example operations of process 500, in some implementations, process 500 includes additional operations, fewer operations, different operations, or differently ordered operations than those depicted in FIGS. 5A-5D. For example, while the example process 500 is described such that the recess 402 and the first metal layer 206 are formed after formation of the second metal layer 210, the recess 402 and the first metal layer 206 may in some implementations be formed prior to the second metal layer 210 being formed (e.g., an order in which the recess 402/first metal layer 206 and the second metal layer 210 are formed may be reversed). Additionally, or alternatively, two or more of the operations of process 500 may be performed in parallel.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A vertical-cavity surface-emitting laser (VCSEL) array, comprising:
a substrate;
a wafer bonding layer over the substrate;
a first metal layer on or within the wafer bonding layer, the first metal layer including a plurality of first electrodes;
an epitaxial region over the first metal layer and the wafer bonding layer, the epitaxial region being bonded to the wafer bonding layer; and
a second metal layer over the epitaxial region, the second metal layer including a plurality of second electrodes,
wherein the plurality of first electrodes and the plurality of second electrodes form a plurality of matrix addressable subarrays of the VCSEL array, each matrix addressable subarray of the plurality of matrix addressable subarrays including one or more emitters.

2. The VCSEL array of claim 1, wherein the wafer bonding layer comprises an adhesive bonding material.

3. The VCSEL array of claim 1, wherein the wafer bonding layer comprises a solder bonding material.

4. The VCSEL array of claim 1, wherein the wafer bonding layer comprises a thermocompression bonding material.

5. The VCSEL array of claim 1, wherein the epitaxial region comprises an isolation region associated with isolating a first electrode of the plurality of first electrodes from a second electrodes of the plurality of first electrodes.

6. The VCSEL array of claim 5, wherein the isolation region is an ion implantation region.

7. The VCSEL array of claim 5, wherein the isolation region is an etched region.

8. The VCSEL array of claim 1, wherein the VCSEL array further includes an isolation layer between the substrate and the wafer bonding layer.

9. The VCSEL array of claim 1, wherein the plurality of first electrodes is a plurality of cathodes and the plurality of second electrodes is a plurality of anodes.

10. The VCSEL array of claim 1, wherein the VCSEL array is a top-emitting VCSEL array.

11. A method, comprising:
forming an epitaxial region on a first substrate;
forming a first metal layer on a first side of the epitaxial region, the first metal layer including a plurality of first electrodes;
bonding, using a wafer bonding material, the first metal layer and the first side of the epitaxial region to a second substrate such that the first metal layer is between the first side of the epitaxial region and the second substrate;
removing the first substrate to expose a portion of a second side of the epitaxial region; and
forming a second metal layer on the second side of the epitaxial region, the second metal layer including a plurality of second electrodes,
wherein the plurality of first electrodes and the plurality of second electrodes form a plurality of matrix addressable subarrays of an emitter array, each matrix addressable subarray of the plurality of matrix addressable subarrays including one or more emitters.

12. The method of claim 11, wherein the wafer bonding material comprises at least one of an adhesive bonding material, a solder bonding material, or a thermocompression bonding material.

13. The method of claim 11, further comprising forming an isolation region associated with isolating a first electrode of the plurality of first electrodes from a second electrodes of the plurality of first electrodes.

14. A vertical-cavity surface-emitting laser (VCSEL) array, comprising:
a substrate comprising a recess on a first side of the substrate;
a first metal layer within the recess on the first side of the substrate, the first metal layer including a plurality of first electrodes;
an epitaxial region on a second side of the substrate; and
a second metal layer over the epitaxial region, the second metal layer including a plurality of second electrodes,
wherein the plurality of first electrodes and the plurality of second electrodes form a plurality of matrix addressable subarrays of the VCSEL array, each matrix addressable subarray of the plurality of matrix addressable subarrays including one or more emitters.

15. The VCSEL array of claim 14, wherein a width of an electrode in the plurality of first electrodes is greater than 10 micrometers.

16. The VCSEL array of claim 14, wherein the recess has a depth that is less than approximately 100 micrometers.

17. The VCSEL array of claim 14, wherein a thickness of the substrate within the recess is approximately 20 micrometers.

18. The VCSEL array of claim 14, wherein the epitaxial region comprises an isolation region associated with isolating a first electrode of the plurality of first electrodes from a second electrode of the plurality of first electrodes.

19. The VCSEL array of claim 14, wherein the VCSEL array further includes an isolation layer between the substrate and the epitaxial region.

20. The VCSEL array of claim 14, wherein the plurality of first electrodes is a plurality of cathodes and the plurality of second electrodes is a plurality of anodes.
